(19) United States
(12) Patent Application Publication
(10) Pub. No.: US 2022/0033959 A1
(43) Pub. Date: Feb. 3, 2022

(54) CRUCIBLE APPARATUS AND DEPOSITION APPARATUS INCLUDING THE SAME

(71) Applicant: SAMSUNG DISPLAY CO., LTD., Yongin-si (KR)

(72) Inventors: Dongkyu Seo, Yongin-si (KR); Daeho Lee, Seoul (KR); Yeongrong Park, Osan-si (KR); Junyong Shin, Uiwang-si (KR); Byeongwook Yoo, Hwaseong-si (KR); Byungseok Lee, Suwon-si (KR)

(21) Appl. No.: 17/222,895

(22) Filed: Apr. 5, 2021

(30) Foreign Application Priority Data
Jul. 30, 2020 (KR) 10-2020-0095345

(51) Int. Cl. C23C 14/24; C23C 14/14; C23C 14/58

(52) U.S. Cl. CPC C23C 14/243; C23C 14/5873; C23C 14/14

(57) ABSTRACT

An apparatus for making substrates of a display device includes: a crucible to vaporize a deposition material and including a first metal; and a sacrificial material electrically connected to the crucible and including a second metal having a second ionization energy less than a first ionization energy of the first metal.

### CROSS-REFERENCE TO RELATED APPLICATION(S)

This application claims priority from and the benefit of Korean Patent Application No. 10-2020-0095345, filed on Jul. 30, 2020, which is hereby incorporated by reference for all purposes as if fully set forth herein.

### BACKGROUND

### Field

Embodiments of the invention relate generally to a crucible apparatus, and more particularly, to a deposition apparatus including the same.

### Discussion of the Background

The organic light emitting display device includes an organic light emitting diode, and the organic light emitting diode includes a cathode for injecting electrons, an anode for injecting holes, and an emission layer disposed between the cathode and the anode. The emission layer includes a plurality of functional layers. For example, the emission layer includes a hole injection layer, a hole transport layer, an organic emission layer, an electron transport layer, and an electron injection layer. In the process of forming the organic light emitting diode, functional layers are generally formed using a thermal vacuum deposition process (hereinafter, referred to as a deposition process). The deposition process refers to a process in which a deposition material which forms the functional layers is stored in a crucible apparatus, and then the deposition material is vaporized and deposited on a surface of a substrate of the organic light emitting display device. After the deposition process is completed, the inside of the crucible apparatus may be cleaned.

The above information disclosed in this Background section is only for understanding of the background of the inventive concepts, and, therefore, it may contain information that does not constitute prior art.

### SUMMARY

Applicant discovered that in the process of cleaning a crucible apparatus used to deposit material to form the substrate of a display device, the deposition material residue, which is the residue of the deposition material, may react with the crucible apparatus due to the cleaning liquid. Accordingly, the crucible apparatus may be corroded, and the metal forming the crucible apparatus may be deposited on the substrate. Accordingly, the organic light emitting display device containing the substrate made with the crucible apparatus may be defective and/or have increased power consumption, and the reliability of the crucible device reduced.

Crucible and deposition apparatus constructed according to the principles and illustrative implementations of the invention are capable of avoiding one or more of the above-noted drawbacks and reducing power consumption in the display device made by the crucible and deposition apparatus. For example, the deposition apparatus may include a crucible apparatus having a crucible and a sacrificial material electrically connected to the crucible. The crucible may include a first metal, and the sacrificial material may include a second metal having a second ionization energy less than a first ionization energy of the first metal. Accordingly, the deposition material residue may react with the second metal and may not react with the first metal. While the crucible is not corroded, the sacrificial material may be corroded, and the reliability of the crucible may be improved.

Additional features of the inventive concepts will be set forth in the description which follows, and in part will be apparent from the description, or may be learned by practice of the inventive concepts.

According to one aspect of the invention, an apparatus for making substrates of a display device includes: a crucible to vaporize a deposition material and including a first metal; and a sacrificial material electrically connected to the crucible and including a second metal having a second ionization energy less than a first ionization energy of the first metal.

The second metal may include an alkali metal.

The second metal may include an alkaline earth metal.

The second metal may include at least one of magnesium, aluminum, calcium, and zinc.

The first metal may include at least one of iron, nickel, manganese, a stainless steel, titanium, and tantalum.

The deposition material may include a halogen compound.

The crucible may include a crucible unit and the sacrificial material may include a sacrificial unit disposed outside the crucible unit.

The sacrificial material including a sacrificial unit may be coupled to the crucible unit.

The sacrificial unit material at least partially may surround the crucible unit.

The sacrificial unit is disposed at least partially under the crucible unit.

The sacrificial until may be electrically connected to the crucible unit by a wire.

The second metal may include a source of electrons to be transferred to the first metal.

According to another aspect of the invention, a deposition apparatus includes: a deposition chamber in which a substrate may be received; a crucible disposed under the substrate; and a heating apparatus disposed outside the crucible to apply heat to the crucible, and wherein the crucible includes: a housing to receive and vaporize a deposition material and including a first metal; and a sacrificial material electrically connected to the housing and including a second metal having a second ionization energy less than a first ionization energy of the first metal.

The second metal may include at least one of magnesium, aluminum, calcium, and zinc.

The sacrificial material may be disposed at least partially outside the crucible.

The sacrificial material may be coupled to the crucible.

The sacrificial material may at least partially surround the housing.

The sacrificial material may be disposed underneath the housing.

The sacrificial material may be electrically connected to the housing by a wire.

The second metal may include a source of electrons to be transferred to the first metal.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a cross-sectional view illustrating an embodiment of a deposition apparatus constructed according to the principles of the invention.

FIG. 2 is a cross-sectional view illustrating an embodiment of a crucible apparatus constructed according to the principles of the invention included in the deposition apparatus of FIG. 1.

FIG. 3 is a cross-sectional view illustrating another embodiment of a deposition apparatus constructed according to the principles of the invention.

FIG. 4 is a cross-sectional view illustrating another embodiment of a crucible apparatus included in the deposition apparatus of FIG. 3.

FIG. 5 is a cross-sectional view illustrating a further embodiment of a deposition apparatus constructed according to the principles of the invention.

FIG. 6 is a cross-sectional view illustrating a further embodiment of a crucible apparatus constructed according to the principles of the invention included in the deposition apparatus of FIG. 5.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing illustrative features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the illustrative term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

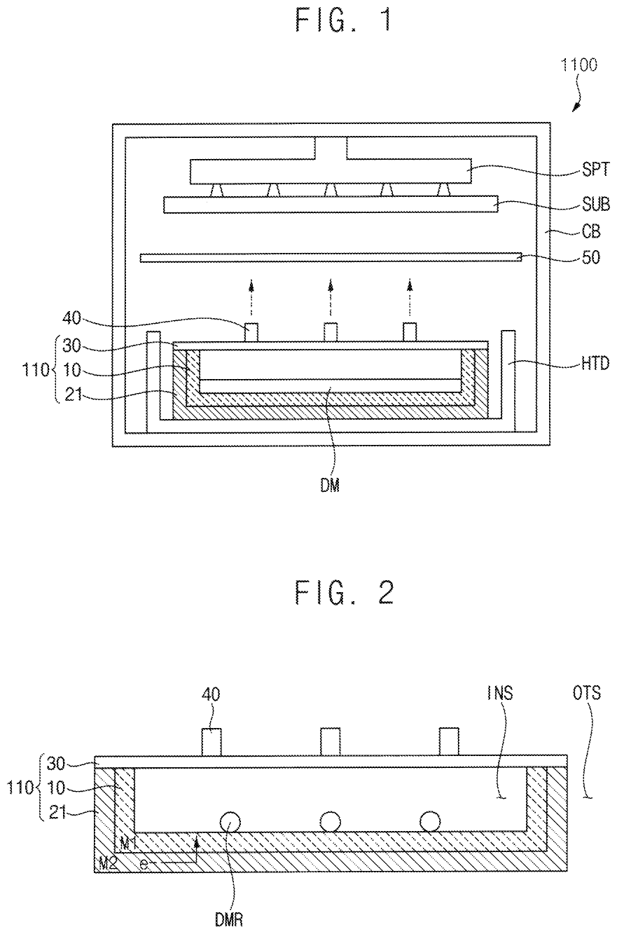

FIG. 1 is a cross-sectional view illustrating an embodiment of a deposition apparatus constructed according to the principles of the invention. FIG. 2 is a cross-sectional view illustrating an embodiment of a crucible apparatus constructed according to the principles of the invention included in the deposition apparatus of FIG. 1.

Referring to FIG. 1, a deposition apparatus 1100 may include a deposition chamber CB, a crucible apparatus 110, and a heating apparatus HTD.

A substrate SUB may be disposed inside the deposition chamber CB. For example, a support member SPT may be formed in an upper portion of the deposition chamber CB, and the substrate SUB may be positioned in the deposition chamber CB by the support member SPT. The substrate SUB in which a deposition process has not been performed may be introduced into the upper portion of the deposition chamber CB, and the substrate SUB in which the deposition process has been performed may be carried out to the outside of the deposition chamber CB.

The deposition chamber CB may provide a process space for performing the deposition process. For example, the deposition chamber CB may be connected to a vacuum pump. Accordingly, the inside of the deposition chamber CB may be in a vacuum state.

The crucible apparatus 110 may be disposed under the substrate SUB. For example, the crucible apparatus 110 may be disposed on a bottom surface of the deposition chamber CB. The crucible apparatus 110 may deposit a deposition material DM on a surface of the substrate SUB. For example, the deposition material DM may be vaporized, and the vaporized deposition material DM may be sprayed through a nozzle 40.

The deposition material DM may be a material for forming a display device. For example, the display device may include an emission layer, a metal layer, and an organic layer. The emission layer may have a structure in which a hole injection layer, a hole transport layer, an organic emission layer, an electron transport layer, and an electron injection layer are sequentially stacked. In an embodiment, the deposition material DM may include a halogen compound for forming the electron injection layer. For example, the deposition material DM may include at least one of fluorine (“F”), chlorine (“Cl”), bromine (“Br”), and iodine (“I”). In another embodiment, the deposition material DM may include a metal material for forming the metal layer or an organic material for forming the organic layer.

The heating apparatus HTD may be disposed outside the crucible device 110. The heating apparatus HTD may apply heat to the crucible apparatus 110. As the heat is applied to the crucible apparatus 110, the crucible device 110 may vaporize the deposition material DM.

The mask 50 may be disposed between the substrate SUB and the crucible apparatus 110. For example, the mask 50 may include an opened region and a closed region. The opened region may pass the deposition material DM proceeding from the bottom of the deposition chamber CB to the top of the deposition chamber CB, and the closed region may block the deposition material DM. Accordingly, a pattern in which the deposition material DM is partially deposited may be formed on the surface of the substrate SUB.

Referring to FIG. 2, the apparatus 110 may include a crucible, e.g., a crucible apparatus, in the form of a crucible housing or unit 10, a sacrificial material in the form of a sacrificial unit 21, and a cover 30. The cover 30 may cover an opening of the crucible unit 10.

The crucible unit 10 may vaporize the deposition material DM stored in an interior INS of the crucible unit 10. For example, the heating apparatus HTD may apply heat to the crucible unit 10, and the crucible unit 10 may transfer the heat to the deposition material DM.

In an embodiment, the crucible unit 10 may include a first metal M1. The first metal M1 may be a metal having high thermal conductivity, high strength, and high sublimation point. For example, the first metal M1 may include at least one of iron (“Fe”), nickel (“Ni”), manganese (“Mn”), a stainless steel (“SUS”), titanium (“Ti”), and tantalum (“Ta”). In addition, the crucible unit 10 may be formed by coating a metal having high strength such as the stainless steel (“SUS”) on a metal having high thermal conductivity such as at least one of copper (“Cu”) and aluminum (“Al”).

In an embodiment, the sacrificial unit 21 may be electrically connected to the crucible apparatus 10 and may include a second metal M2. The second metal M2 may be a metal having low ionization energy and high ionization tendency. For example, the second metal M2 may include an alkali metal and/or an alkaline earth metal. In addition, the second metal M2 may include at least one of magnesium (“Mg”), aluminum (“Al”), calcium (“Ca”), and zinc (“Zn”).

In an embodiment, a first ionization energy of the first metal M1 may be greater than a second ionization energy of the second metal M2. In other words, the ionization tendency of the first metal M1 may be smaller than the ionization tendency of the second metal M2.

After the deposition process is completed, a process of cleaning the interior INS of the crucible unit 10 may be performed. The cleaning process is performed using a cleaning liquid, and the cleaning liquid may be distilled water and/or an acidic solution. During the cleaning process, the deposition material residue DMR, which is the residue of the deposition material DM, may react with the metal due to the cleaning solution, and thus the unit including the metal M1 may be corroded.

As a conventional crucible apparatus does not include the sacrificial unit, the deposition material residue DMR may react with the first metal M1 by the cleaning solution. Accordingly, the crucible unit is corroded. When the crucible unit is corroded, the first metal M1 may be vaporized during the deposition process. Accordingly, the first metal M1 may be deposited on the substrate SUB, and defect may be introduced into in the display device.

However, the crucible apparatus 110 according to an embodiment may include the sacrificial unit 21. Accordingly, the deposition material residue DMR may react with the second metal M2 by the cleaning solution. In other words, the second metal M2 may provide electrons e″ to the first metal M1. Accordingly, the crucible unit 10 may not be corroded, and the sacrificial unit 21 may be corroded. As the crucible unit 10 is not corroded, the first metal M1 may not be vaporized during the deposition process. Accordingly, the first metal M1 may not be deposited on the substrate SUB, and reliability of the crucible device 110 may be improved.

In an embodiment, the sacrificial unit 21 may be disposed at an outside OTS of the crucible unit 10. For example, as shown in FIG. 2, the sacrificial unit 21 may contact the crucible unit 10 and may at least partially surround the crucible unit 10. Accordingly, the second metal M2 may provide electrons e⁻ to the first metal M1, and the crucible unit 10 may not be corroded.

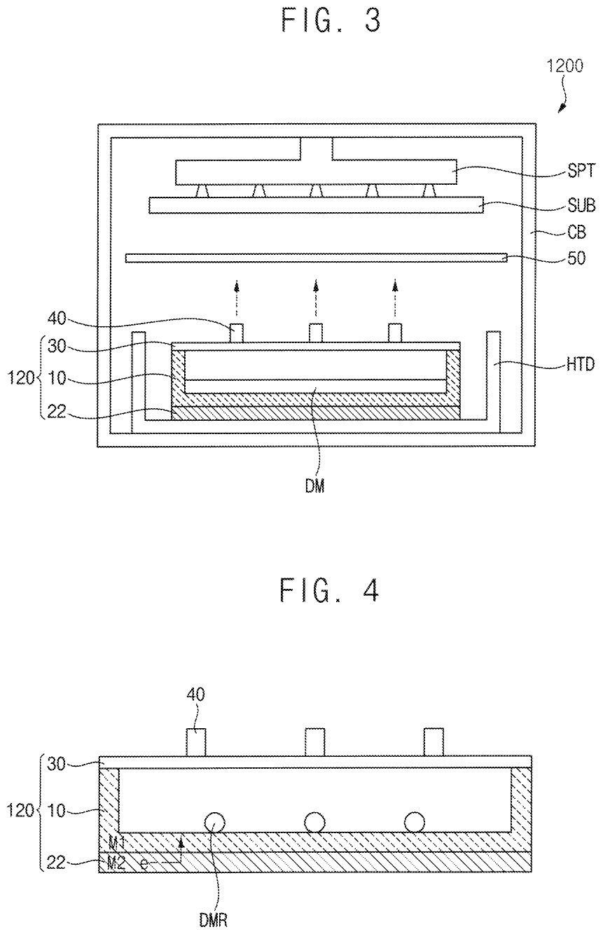

FIG. 3 is a cross-sectional view illustrating another embodiment of a deposition apparatus constructed according to the principles of the invention. FIG. 4 is a cross-sectional view illustrating another embodiment of a crucible apparatus included in the deposition apparatus of FIG. 3.

Referring to FIG. 3, a deposition apparatus 1200 may include the deposition chamber CB, a crucible apparatus 120, and the heating apparatus HTD. The support member SPT and the mask 50 may be disposed inside the deposition chamber CB. However, the deposition chamber CB, the heating apparatus HTD, the support member SPT, and the mask 50 of the deposition apparatus 1200 are substantially the same as the deposition chamber CB, the heating apparatus HTD, the support member SPT, and the mask 50 described above with reference to FIG. 1.

Referring to FIG. 4, the crucible device 120 may include a crucible unit 10, a sacrificial unit 22, and a cover 30. The cover 30 may cover an opening of the crucible unit 10.

The crucible unit 10 may vaporize the deposition material DM stored in an interior INS, as depicted in FIG. 2, of the crucible unit 10, as discussed above. For example, the heating apparatus HTD may apply the heat to the crucible unit 10, and the crucible unit 10 may transfer the heat to the deposition material DM.

The crucible unit 10 may include a first metal M1. The first metal M1 may be a metal having high thermal conductivity, high strength, and high sublimation point. For example, the first metal M1 may include at least one of iron (“Fe”), nickel (“Ni”), manganese (“Mn”), a stainless steel (“SUS”), titanium (“Ti”), and tantalum (“Ta”). In addition, the crucible unit 10 may be formed by coating a metal having high strength such as a stainless steel (“SUS”) on a metal having high thermal conductivity such as at least one of copper (“Cu”) and aluminum (“Al”).

The sacrificial unit 22 may be electrically connected to the crucible apparatus 10 and may include a second metal M2. The second metal M2 may be a metal having low ionization energy and high ionization tendency. For example, the second metal M2 may include an alkali metal and/or an alkaline earth metal. In addition, the second metal M2 may include at least one of magnesium (“Mg”), aluminum (“Al”), calcium (“Ca”), and zinc (“Zn”).

A first ionization energy of the first metal M1 may be greater than a second ionization energy of the second metal M2. In other words, the ionization tendency of the first metal M1 may be smaller than the ionization tendency of the second metal M2.

Accordingly, the deposition material residue DMR may react with the second metal M2 due to the cleaning solution. In other words, the second metal M2 may provide electrons e⁻ to the first metal M1. Accordingly, the crucible unit 10 may not be corroded, and the sacrificial unit 22 may be corroded. As the crucible unit 10 is not corroded, the first metal M1 may not be vaporized during the deposition process. Accordingly, the first metal M1 may not be deposited on the substrate SUB, and reliability of the crucible device 120 may be improved.

The sacrificial unit 22 may be disposed at an outside OTS of the crucible unit 10. For example, as shown in FIG. 4, the sacrificial unit 22 may contact the crucible unit 10 and may be disposed underneath the crucible unit 10. Accordingly, the second metal M2 may provide electrons e⁻ to the first metal M1, and the crucible unit 10 may not be corroded.

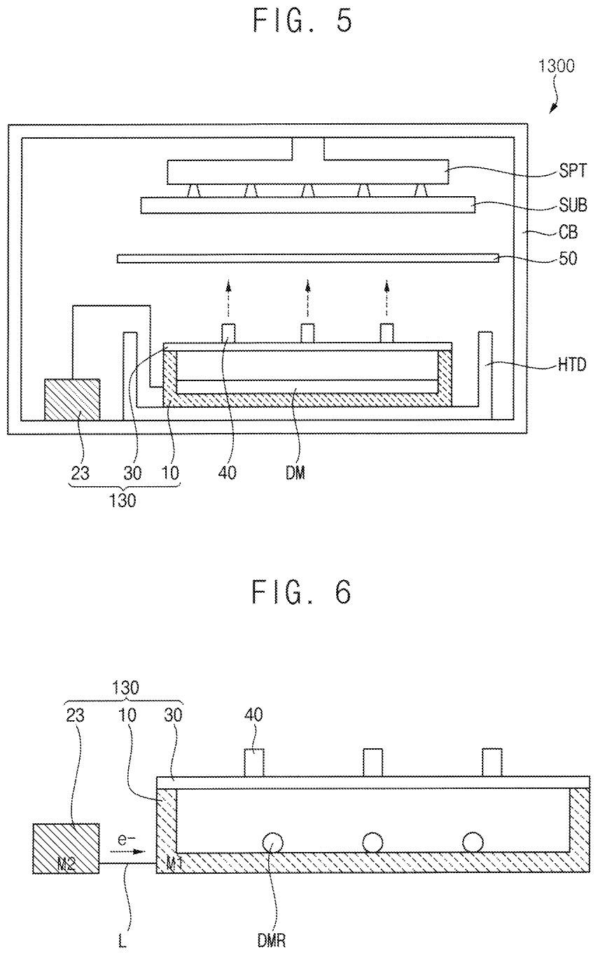

FIG. 5 is a cross-sectional view illustrating a further embodiment of a deposition apparatus constructed according to the principles of the invention. FIG. 6 is a cross-sectional view illustrating a further embodiment of a crucible apparatus constructed according to the principles of the invention included in the deposition apparatus of FIG. 5.

Referring to FIG. 5, a deposition apparatus 1300 according to still another embodiment may include the deposition chamber CB, a crucible apparatus 130, and the heating apparatus HTD. The support member SPT and the mask 50 may be disposed inside the deposition chamber CB. However, the deposition chamber CB, the heating apparatus HTD, the support member SPT, and the mask 50 of the deposition apparatus 1300 are substantially the same as the deposition chamber CB, the heating apparatus HTD, the support member SPT, and the mask 50 described above with reference to FIG. 1.

Referring to FIG. 6, the crucible device 130 may include a crucible unit 10, a sacrificial unit 23, and a cover 30. The cover 30 may cover an opening of the crucible unit 10.

The crucible unit 10 may vaporize the deposition material DM stored in an interior INS, as depicted in FIG. 2, of the crucible unit 10, as discussed above. For example, the heating apparatus HTD may apply the heat to the crucible unit 10, and the crucible unit 10 may transfer the heat to the deposition material DM.

The crucible unit 10 may include a first metal M1. The first metal M1 may be a metal having high thermal conductivity, high strength, and high sublimation point. For example, the first metal M1 may include at least one of iron (“Fe”), nickel (“Ni”), manganese (“Mn”), a stainless steel (“SUS”), titanium (“Ti”), and tantalum (“Ta”). In addition, the crucible unit 10 may be formed by coating a metal having high strength such as a stainless steel (“SUS”) on a metal having high thermal conductivity such as at least one of copper (“Cu”) and aluminum (“Al”).

The sacrificial unit 23 may be electrically connected to the crucible apparatus 10 and may include a second metal M2. The second metal M2 may be a metal having low ionization energy and high ionization tendency. For example, the second metal M2 may include an alkali metal and/or an alkaline earth metal. In addition, the second metal M2 may include at least one of magnesium (“Mg”), aluminum (“Al”), calcium (“Ca”), and zinc (“Zn”).

A first ionization energy of the first metal M1 may be greater than a second ionization energy of the second metal M2. In other words, the ionization tendency of the first metal M1 may be smaller than the ionization tendency of the second metal M2.

Accordingly, the deposition material residue DMR may react with the second metal M2 due the cleaning solution. In other words, the second metal M2 may provide electrons e⁻ to the first metal M1. Accordingly, the crucible unit 10 may not be corroded, and the sacrificial unit 23 may be corroded. As the crucible unit 10 is not corroded, the first metal M1 may not be vaporized during the deposition process. Accordingly, the first metal M1 may not be deposited on the substrate SUB, and reliability of the crucible device 110 may be improved.

The sacrificial unit 23 may be disposed at an outside OTS of the crucible unit 10. For example, as shown in FIG. 6, the sacrificial unit 23 may be disposed adjacent to a side of, and be electrically connected to, the crucible unit 10 by a wire L. Accordingly, the second metal M2 may provide electrons e⁻ to the first metal M1, and the crucible unit 10 may not be corroded.

According to the principles and illustrative embodiments of the invention a deposition apparatus may include a crucible apparatus having a crucible and a sacrificial material electrically connected to the crucible unit. The crucible unit may include a first metal, and the sacrificial unit may include a second metal having a second ionization energy less than a first ionization energy of the first metal. Accordingly, the deposition material residue may react with the second metal and may not react with the first metal. Accordingly, the crucible is not corroded, the sacrificial material may be corroded, and the reliability of the crucible device may be improved.

Although certain illustrative embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An apparatus for making substrates of a display device, the apparatus comprising:
a crucible to vaporize a deposition material and including a first metal; and
a sacrificial material electrically connected to the crucible and including a second metal having a second ionization energy less than a first ionization energy of the first metal.

2. The apparatus of claim 1, wherein the second metal comprises an alkali metal.

3. The apparatus of claim 1, wherein the second metal comprises an alkaline earth metal.

4. The apparatus of claim 1, wherein the second metal comprises at least one of magnesium, aluminum, calcium, and zinc.

5. The apparatus of claim 1, wherein the first metal comprises at least one of iron, nickel, manganese, a stainless steel, titanium, and tantalum.

6. The apparatus of claim 1, wherein the deposition material comprises a halogen compound.

7. The apparatus of claim 1, wherein the crucible comprises a crucible unit and the sacrificial material comprises a sacrificial unit disposed outside the crucible unit.

8. The apparatus of claim 7, wherein the sacrificial material comprising a sacrificial unit is coupled to the crucible unit.

9. The apparatus of claim 8, wherein the sacrificial unit at least partially surrounds the crucible unit.

10. The apparatus of claim 8, wherein the sacrificial unit is disposed at least partially under the crucible unit.

11. The apparatus of claim 7, wherein the sacrificial until is electrically connected to the crucible unit by a wire.

12. The apparatus of claim 1, wherein the second metal comprises a source of electrons to be transferred to the first metal.

13. A deposition apparatus comprising:
a deposition chamber in which a substrate may be received;
a crucible disposed under the substrate; and
a heating apparatus disposed outside the crucible to apply heat to the crucible, and
wherein the crucible comprises:
a housing to receive and vaporize a deposition material and including a first metal; and
a sacrificial material electrically connected to the housing and including a second metal having a second ionization energy less than a first ionization energy of the first metal.

14. The deposition apparatus of claim 13, wherein the second metal comprises at least one of magnesium, aluminum, calcium, and zinc.

15. The deposition apparatus of claim 13, wherein the sacrificial material is disposed at least partially outside the crucible.

16. The deposition apparatus of claim 15, wherein the sacrificial material is coupled to the crucible.

17. The deposition apparatus of claim 16, wherein the sacrificial material at least partially surrounds the housing.

18. The deposition apparatus of claim 16, wherein the sacrificial material is disposed underneath the housing.

19. The deposition apparatus of claim 13, wherein the sacrificial material is electrically connected to the housing by a wire.

20. The deposition apparatus of claim 13, wherein the second metal comprises a source of electrons to be transferred to the first metal.
